(19) United States
(12) Patent Application Publication
(10) Pub. No.: US 2019/0281712 A1
(43) Pub. Date: Sep. 12, 2019

(54) FIXING STRUCTURE AND ELECTRONIC DEVICE COMPRISING THE SAME

(71) Applicant: CHICONY POWER TECHNOLOGY CO., LTD., New Taipei City (TW)

(72) Inventor: Chao-Cheng CHENG, New Taipei City (TW)

(21) Appl. No.: 15/947,118

(22) Filed: Apr. 6, 2018

(30) Foreign Application Priority Data
Mar. 8, 2018 (TW) 107107955

(51) Int. Cl. H05K 5/02

(52) U.S. Cl. CPC H05K 5/0217

(57) ABSTRACT

A fixing structure includes a first fixing member and a second fixing member. The first fixing member is disposed in a first housing, and a first distance is defined between the first fixing member and a bottom wall of the first housing. The second fixing member is disposed on a side wall of a second housing and includes a base and a cantilever. The base is separated from the first fixing member. A second distance is defined between the base and the bottom wall of the first housing, and the first distance is greater than the second distance. The cantilever is connected to the base and located between the base and the first fixing member. The cantilever contacts against the first fixing member to fix the first housing to the second housing. An electronic device including the fixing structure is also provided.

### CROSS REFERENCE TO RELATED APPLICATIONS

This Non-provisional application claims priority under 35 U.S.C. § 119(a) on Patent Application No(s). 107107955 filed in Taiwan, Republic of China on Mar. 8, 2018, the entire contents of which are hereby incorporated by reference.

### BACKGROUND

### Technology Field

The present disclosure relates to a fixing structure and, in particular, to a fixing structure that can provide a fixing function for a long term and still provide the fixing function under the influence of external force. This disclosure also relates to an electronic device containing the above fixing structure.

### Description of Related Art

In the assembling process of most electronic products, two components of the electronic product is usually connected by screws or engaging structures. However, the additional tool (e.g. a screw driver) is required for utilizing the screws to connect the components. In general, the engaging structures include a recess disposed on the first component, and a hook disposed on the second component. This design can fix the individual components. Besides, a reverse force can be applied to detach the two components.

Therefore, it is desired to provide a fixing structure that can provide a fixing function for a long term and still provide the fixing function under the influence of external force, and an electronic device containing the fixing structure.

### SUMMARY

An objective of the disclosure is to provide a fixing structure and an electronic device containing the fixing structure. Compared with the conventional art, the fixing structure and electronic device of this disclosure can provide a fixing function for a long term and still provide the fixing function under the influence of external force, thereby preventing the loosening and detaching of the components without additional fastening mechanism (e.g. ultrasonic welding and screwing). Accordingly, the application of this disclosure is more convenient and has less cost.

This disclosure provides a fixing structure for fixing a first housing to a second housing. The fixing structure includes a first fixing member and a second fixing member. The first fixing member is disposed in the first housing, and a first distance is defined between the first fixing member and a bottom wall of the first housing. The second fixing member is disposed on a side wall of the second housing and includes a base and a cantilever. The base is separated from the first fixing member, and a second distance is defined between the base and the bottom wall of the first housing. The first distance is greater than the second distance. The cantilever is connected to the base and located between the base and the first fixing member. The cantilever contacts against the first fixing member to fix the first housing to the second housing.

In one embodiment, the first fixing member is a protruding block.

In one embodiment, the first fixing member includes a first slant surface and a second slant surface opposite to the first slant surface, the first slant surface is farther from the cantilever than the first slant surface, and the cantilever contacts against the second slant surface.

In one embodiment, the base includes a contacting portion and a connecting portion connecting to the contact portion, and the contact portion contacts against the bottom wall of the first housing.

In one embodiment, the connecting portion connects the contact portion to the cantilever, and the connecting portion is suspended above the bottom wall of the first housing.

In one embodiment, an included angle between the cantilever and the connecting portion is between 95 degrees and 120 degrees.

In one embodiment, a width of the cantilever is greater than a width of the second slant surface.

In one embodiment, the base has an L shape.

The present disclosure also provides an electronic device including a first housing, a second housing and a fixing structure. The second housing is fixed to the first housing. The fixing structure is configured for fixing the first housing to the second housing, and includes a first fixing member and a second fixing member. The first fixing member is disposed in the first housing, and a first distance is defined between the first fixing member and a bottom wall of the first housing. The second fixing member is disposed on a side wall of the second housing and includes a base and a cantilever. The base is separated from the first fixing member, and a second distance is defined between the base and the bottom wall of the first housing. The first distance is greater than the second distance. The cantilever is connected to the base and located between the base and the first fixing member. The cantilever contacts against the first fixing member to fix the first housing to the second housing.

In one embodiment, the first fixing member is a protruding block.

In one embodiment, the first fixing member includes a first slant surface and a second slant surface opposite to the first slant surface, the first slant surface is farther from the cantilever than the first slant surface, and the cantilever contacts against the second slant surface.

In one embodiment, the base includes a contacting portion and a connecting portion connecting to the contact portion, and the contact portion contacts against the bottom wall of the first housing.

In one embodiment, the connecting portion connects the contact portion to the cantilever, and the connecting portion is suspended above the bottom wall of the first housing.

In one embodiment, an included angle between the cantilever and the connecting portion is between 95 degrees and 120 degrees.

In one embodiment, a width of the cantilever is greater than a width of the second slant surface.

In one embodiment, the base has an L shape.

As mentioned above, the fixing structure of the disclosure includes a first fixing member and a second fixing member, which can fix the components of an electronic device for a long term and still provide the fixing function under the influence of external force. This configuration can prevent the loosening and detaching of the components without additional fastening mechanism (e.g. ultrasonic welding and screwing). Accordingly, the application of this disclosure is more convenient and has less cost.

### BRIEF DESCRIPTION OF THE DRAWINGS

The disclosure will become more fully understood from the detailed description and accompanying drawings, which are given for illustration only, and thus are not limitative of the present disclosure, and wherein:

FIG. 1 is a schematic diagram showing a fixing structure according to an embodiment of the disclosure;

FIG. 2 is another schematic diagram showing the fixing structure according to the embodiment of the disclosure;

FIG. 3 is a schematic diagram showing an electronic device according to an embodiment of the disclosure; and

FIG. 4 is another schematic diagram showing the electronic device according to the embodiment of the disclosure.

### DETAILED DESCRIPTION OF THE DISCLOSURE

The present disclosure will be apparent from the following detailed description, which proceeds with reference to the accompanying drawings, wherein the same references relate to the same elements.

A fixing structure and an electronic device containing the fixing structure of this disclosure can provide a fixing function for a long term and still provide the fixing function under the influence of external force, thereby preventing the loosening and detaching of the components without additional fastening mechanism (e.g. ultrasonic welding and screwing). Accordingly, the application of this disclosure is more convenient and has less cost. The structures and features of the fixing structure and electronic device of this disclosure will be further described in the following embodiments.

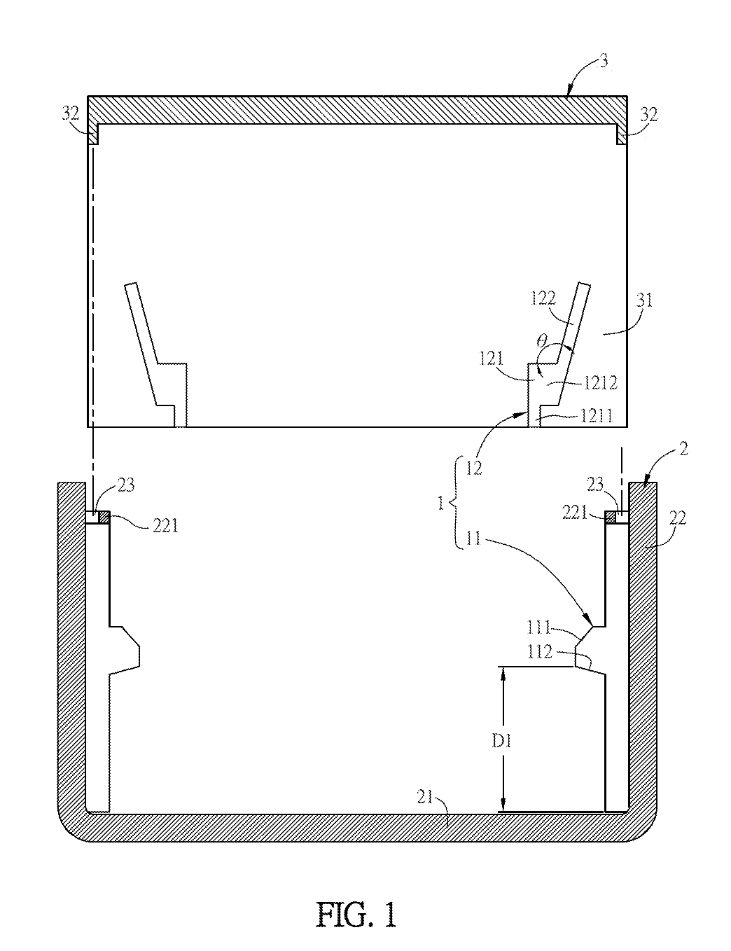

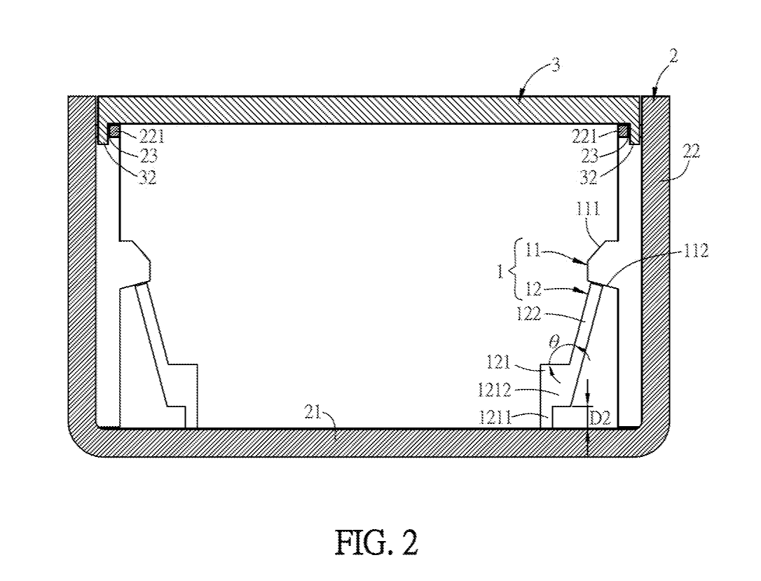

FIGS. 1 and 2 are schematic diagrams showing a fixing structure 1 according to an embodiment of this disclosure. The fixing structure 1 is configured for fixing a first housing 2 to a second housing 3. The fixing structure 1 includes a first fixing member 11 and a second fixing member 12. The first fixing member 11 is disposed in the first housing 2. A first distance D1 is defined between the first fixing member 11 and a bottom wall 21 of the first housing 2. The second fixing member 12 is disposed on a side wall 31 of the second housing 3 and includes a base 121 and a cantilever 122. The base 121 is separated from the first fixing member 11, and a second distance D2 is defined between the base 121 and the bottom wall 21 of the first housing 2. The first distance D1 is greater than the second distance D2. The cantilever 122 is connected to the base 121 and located between the base 121 and the first fixing member 11. The cantilever 122 contacts against the first fixing member 11 to fix the first housing 2 to the second housing 3. In the viewing angle of FIGS. 1 and 2, the first housing 2 has a U shape, and the second housing 3 has a reverse-U shape. When the first housing 2 is assembled to the second housing 3, the entire assembled structure has a rectangular shape. The first fixing member 11 is disposed on the side wall 22 of the first housing 2, and the second fixing member 12 is disposed on the side wall 31 of the second housing 3. The two side walls 22 of the first housing 2 and the two side walls 31 of the second housing 3 can form the four side walls of the rectangular shape.

In this embodiment, the first fixing member 11 is a protruding block.

In this embodiment, the first fixing member 11 includes a first slant surface 111 and a second slant surface 112 opposite to the first slant surface 111. The first slant surface 111 is farther from the cantilever 122 than the first slant surface 112, and the cantilever 122 contacts against the second slant surface 112.

In this embodiment, the base 121 includes a contacting portion 1211 and a connecting portion 1212 connecting to the contact portion 1211, and the contact portion 1211 contacts against the bottom wall 21 of the first housing 2.

In this embodiment, the connecting portion 1212 connects the contact portion 1211 to the cantilever 122, and the connecting portion 1212 is suspended above the bottom wall 21 of the first housing 2. In other words, the distance between the suspended connecting portion 1212 and the bottom wall 21 is equal to the second distance D2.

In this embodiment, an included angle θ between the cantilever 122 and the connecting portion 1212 is between 95 degrees and 120 degrees. Preferably, the included angle θ between the cantilever 122 and the connecting portion 1212 is 105 degrees.

In this embodiment, a width of the cantilever 122 is greater than a width of the second slant surface 112. Preferably, the width of the cantilever 122 is 3 mm, and the width of the second slant surface 112 is 1 mm.

In this embodiment, the base 121 has an L shape. In particular, a part (the contact portion 1211) of the L-shaped base 121 is connected to the side wall 31 of the second housing 3, and another part thereof (the connecting portion 1212) is connected to the cantilever 122.

In this embodiment, the number of the fixing structures 1 can be adjusted based on the actual requirement of the user, and this disclosure is not limited. Similarly, the number of the fixing members can also be adjusted based on the actual requirement of the user, and this disclosure is not limited. The terms “first” and “second” are only for illustrating the amount of the components of this embodiment, and are not to limit the amount of the components of the disclosure.

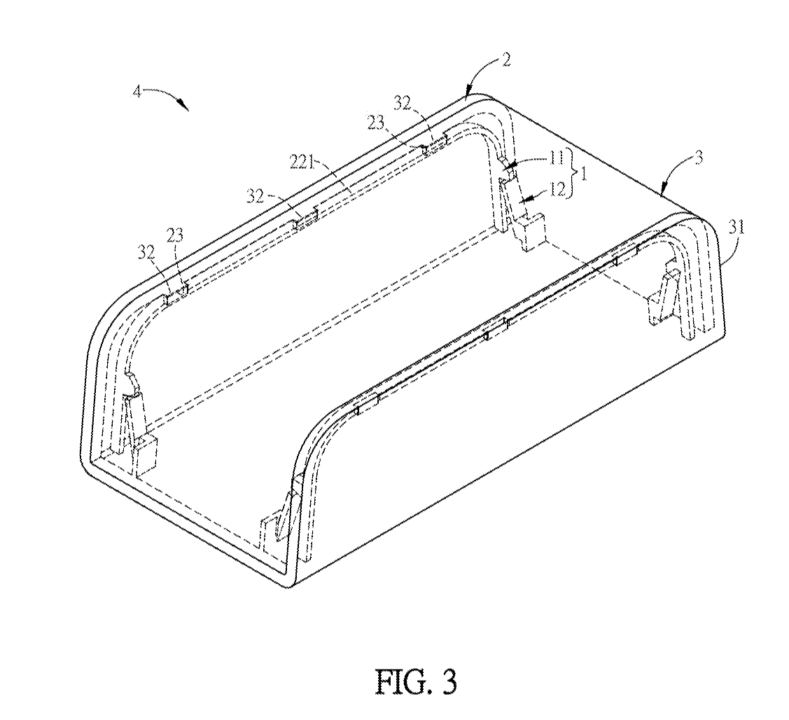

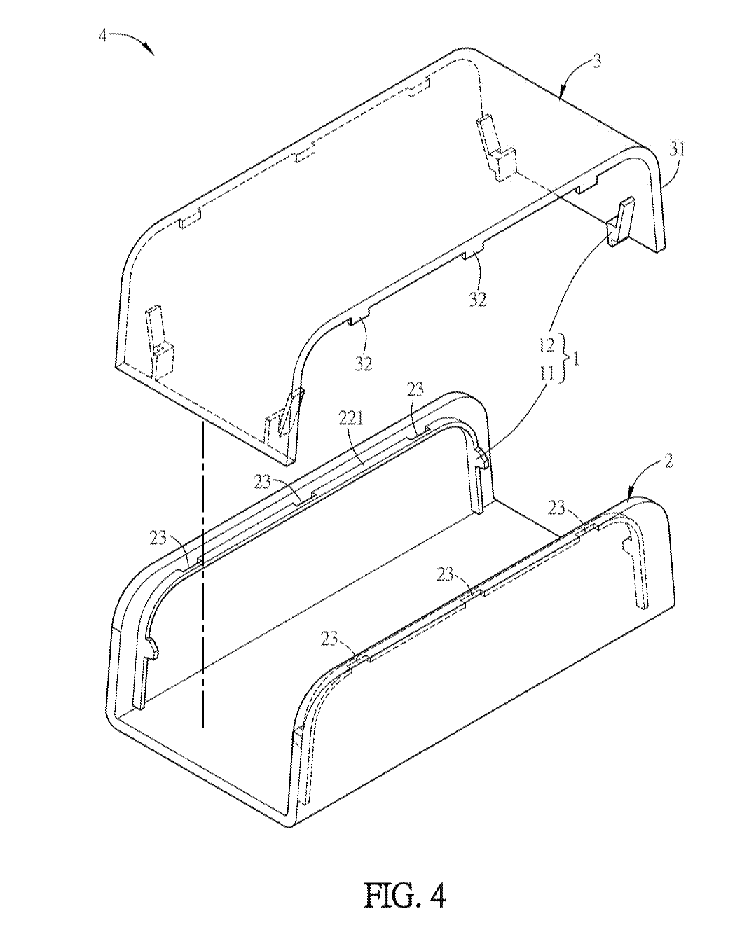

FIGS. 3 and 4 are schematic diagrams showing an electronic device 4 according an embodiment of the disclosure. Referring to FIGS. 3 and 4, the electronic device 4 includes a fixing structure 1, a first housing 2, and a second housing 3. The second housing 3 is fixed to the first housing. The structures, components, and connections of the fixing structure 1, the first housing 2 and the second housing 3 can be referred to the above embodiment, so the detailed descriptions thereof will be omitted. In particular, the second housing 3 is configured with three fixing blocks 32, which are disposed at two sides of the second housing 3 and extended downwardly from the top surface. When the first housing 2 is fixed to the second housing 3, the fixing blocks 32 can be inserted and engaged in the openings 23 of the first housing 2 for limiting the relative movement of the first housing 2 and the second housing 3. In addition, the side wall 22 of the first housing 2 has a side skirt 221 disposed on the side wall 22 and extended inwardly, and the openings 23 and the first fixing member 11 are disposed on the side skirt 221.

To sum up, in the fixing structure 1 and the electronic device 4 including the fixing structure 1 of this disclosure, the first fixing member 11 and the second fixing member 12 (including the base 121 and the cantilever 122) are configured for fixing the components of an electronic device 4 for a long term and still provide the fixing function under the influence of external force. This configuration can prevent the loosening and detaching of the components without additional fastening mechanism (e.g. ultrasonic welding and screwing). Accordingly, the application of this disclosure is more convenient and has less cost. More important, when the second housing 3 is moved upwardly, the cantilever 122 can be forced and increase the interference, which can prevent the second housing 3 from detaching the first housing 2. This configuration can achieve the required effect of this disclosure.

Although the disclosure has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the disclosure.

1. A fixing structure for fixing a first housing to a second housing, comprising:
a first fixing member disposed in the first housing, wherein a first distance is defined between the first fixing member and a bottom wall of the first housing; and
a second fixing member disposed on a side wall of the second housing and comprising:
a base separated from the first fixing member, wherein a second distance is defined between the base and the bottom wall of the first housing, and the first distance is greater than the second distance, and
a cantilever connected to the base and located between the base and the first fixing member, wherein the cantilever contacts against the first fixing member to fix the first housing to the second housing.

2. The fixing structure according to claim 1, wherein the first fixing member is a protruding block.

3. The fixing structure according to claim 1, wherein the first fixing member comprises a first slant surface and a second slant surface opposite to the first slant surface, the first slant surface is farther from the cantilever than the first slant surface, and the cantilever contacts against the second slant surface.

4. The fixing structure according to claim 1, wherein the base comprises a contacting portion and a connecting portion connecting to the contacting portion, and the contacting portion contacts against the bottom wall of the first housing.

5. The fixing structure according to claim 4, wherein the connecting portion connects the contacting portion to the cantilever, and the connecting portion is suspended above the bottom wall of the first housing.

6. The fixing structure according to claim 4, wherein an included angle between the cantilever and the connecting portion is between 95 degrees and 120 degrees.

7. The fixing structure according to claim 3, wherein a width of the cantilever is greater than a width of the second slant surface.

8. The fixing structure according to claim 1, wherein the base has an L shape.

9. An electronic device, comprising:
a first housing;
a second housing fixed to the first housing; and
a fixing structure for fixing the first housing to the second housing, wherein the fixing structure comprises:
a first fixing member disposed in the first housing, wherein a first distance is defined between the first fixing member and a bottom wall of the first housing; and
a second fixing member disposed on a side wall of the second housing and comprising:
a base separated from the first fixing member, wherein a second distance is defined between the base and the bottom wall of the first housing, and the first distance is greater than the second distance, and
a cantilever connected to the base and located between the base and the first fixing member, wherein the cantilever contacts against the first fixing member to fix the first housing to the second housing.

10. The electronic device according to claim 9, wherein the first fixing member is a protruding block.

11. The electronic device according to claim 9, wherein the first fixing member comprises a first slant surface and a second slant surface opposite to the first slant surface, the first slant surface is farther from the cantilever than the first slant surface, and the cantilever contacts against the second slant surface.

12. The electronic device according to claim 9, wherein the base comprises a contacting portion and a connecting portion connecting to the contacting portion, and the contacting portion contacts against the bottom wall of the first housing.

13. The electronic device according to claim 12, wherein the connecting portion connects the contacting portion to the cantilever, and the connecting portion is suspended above the bottom wall of the first housing.

14. The electronic device according to claim 12, wherein an included angle between the cantilever and the connecting portion is between 95 degrees and 120 degrees.

15. The electronic device according to claim 11, wherein a width of the cantilever is greater than a width of the second slant surface.

16. The electronic device according to claim 9, wherein the base has an L shape.

17. The fixing structure according to claim 1, wherein the cantilever extends from the base toward the first fixing member, and a top end surface of the cantilever contacts against the first fixing member to fix the first housing to the second housing.

18. The fixing structure according to claim 17, wherein a contacting portion of the base and the top end surface of the cantilever are respectively at two opposite sides of the second fixing member, and the contacting portion of the base contacts against the bottom wall of the first housing.

19. The fixing structure according to claim 1, wherein each of the two side walls of the first housing is adjacent to each of the two side walls of the second housing to form four side walls of a rectangular shape.

20. The fixing structure according to claim 1, wherein the cantilever is deformable.
